(19) United States
(12) Patent Application Publication
(10) Pub. No.: US 2026/0059866 A1
(43) Pub. Date: Feb. 26, 2026

(54) ESD SOLUTION FOR 3DIC DIE-TO-DIE INTERFACE

(71) Applicant: Taiwan Semiconductor Manufacturing Company, Ltd., Hsinchu (TW)

(72) Inventors: Shang-Yi Yang, Hsinchu City (TW); Tzu-Heng Chang, Hsinchu City (TW)

(73) Assignee: Taiwan Semiconductor Manufacturing Company, Ltd., Hsinchu (TW)

(21) Appl. No.: 18/810,780

(22) Filed: Aug. 21, 2024

(51) Int. Cl. H01L 27/02; H01L 23/00; H01L 23/48; H01L 25/00; H01L 25/065; H01L 29/74

(52) U.S. Cl. CPC H10D 89/931; H01L 23/481; H01L 25/0657; H01L 25/50; H10D 84/135; H01L 24/08; H01L 2224/08146; H01L 2225/06527; H01L 2225/06544

(57) ABSTRACT

A semiconductor package includes at least a first die. The first die includes an internal circuit disposed on a substrate, an electrostatic discharge (ESD) protection circuit disposed on the substrate but laterally spaced from the internal circuit and including a first charge dissipation element, and a first Silicon Controlled Rectifier (SCR) laterally adjacent to and spaced from the first charge dissipation element.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has grown a need for smaller and more advanced packaging techniques of semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically illustrates a cross-sectional view of an example semiconductor package in accordance with some embodiments.

FIG. 2 is a cross-sectional view of a semiconductor package illustrating a potential plasma process-induced damage (PID).

FIG. 3 illustrates a circuit including a combo Silicon Controlled Rectifier (SCR) structure having a combination of an electrostatic discharge (ESD) protection circuit and at least a SCR component in accordance with some embodiments.

FIG. 4 illustrates an example SCR component in accordance with some embodiments.

FIG. 5 is a cross-sectional view of a semiconductor package including a combo SCR structure in FIG. 3 in accordance with some embodiments.

FIGS. 6, 7 and 8 illustrate various SCR components in accordance with some embodiments.

FIG. 9 is a cross-sectional view of an example combo SCR structure in a die of a package in accordance with some embodiments.

FIG. 10 illustrates a layout of an example combo SCR structure in accordance with some embodiments.

FIG. 11 is an example flowchart of a method for fabricating a semiconductor package in accordance with some embodiments.

FIGS. 12, 13, 14, 15 and 16 are cross-sectional views of the semiconductor package of FIG. 5 at various stages of the method of FIG. 11 in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As semiconductor technologies further advance, stacked semiconductor devices, such as 3D integrated circuits (3D ICs or 3D-ICs), have emerged as an effective alternative to further reduce the physical size of a semiconductor device. In a stacked semiconductor device, active circuits such as logic, memory, processor circuits and the like are fabricated on different semiconductor wafers (substrates), forming respective semiconductor dies. Two or more semiconductor wafers (or dies) may be arranged on top of one another to further reduce the form factor of the semiconductor device.

Two or more semiconductor wafers or dies (e.g., a bottom die, a top die, and a middle die) may be bonded together through suitable bonding techniques such as, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like. An electrical connection may be provided between the stacked semiconductor dies based on a number of through via structures, such as through substrate vias (TSV) (e.g., through silicon vias) or the like.

However, during processes of forming 3D integrated circuits, a large number of electrostatic charges can be generated and accumulated in or near components, such as TSVs. Such electrostatic charges can disadvantageously cause damage to devices, components, and interconnects formed in the 3D IC (such as in the top die and in the bottom die) when the electrostatic charges are released in a sudden way. For example, during a plasma etching process, a large number of plasma induced electrostatic charges can be generated and accumulated in or near the TSVs, and thus may cause a so-called Plasma Induced Damage (PID) when they are released in a sudden way. In addition, electrostatic charges generated and accumulated during the operation or usage of the 3DIC can also cause damage to the devices, the components, and the interconnects that are formed in the 3D IC when they are released in a sudden way. Thus, a protective electrostatic discharge (ESD) device or mechanism, which is able to efficiently discharge the accumulated electrostatic charges and is space-efficient, is highly desired.

The present disclosure provides various embodiments of a semiconductor package. In some embodiments, the semiconductor package includes a first die that includes an internal circuit, an electrostatic discharge (ESD) protection circuit, and a first Silicon Controlled Rectifier (SCR) component. The internal circuit is disposed along a major surface of a substrate. The ESD protection circuit is also disposed along the major surface of the substrate, laterally adjacent to and spaced from the internal circuit, and includes a first charge dissipation element. The first SCR component is laterally adjacent to and spaced from the first charge dissipation element. In some embodiments, the semiconductor package further includes a second die vertically coupled to the first die by a bonding interface, the bonding interface including a plurality of micro-bumps or hybrid bonds. In some embodiments, the first SCR component is selected from a group consisting of a PMOS transistor, a NMOS transistor, a diode, and a bipolar junction transistor (BJT). In some embodiments, the first charge dissipation element is electrically coupled between a first power line Vss and a second power line Vdd, and the first SCR component is adjacent to but spaced from one of the first and the second power lines. Such a combined or combo SCR structure including the first SCR component and the first charge dissipation element in the semiconductor package can improve discharge of electrostatic charges generated during the processes of forming some components (such as TSVs) in the first die or during the operations of the semiconductor package, and can also improve integration of the dies.

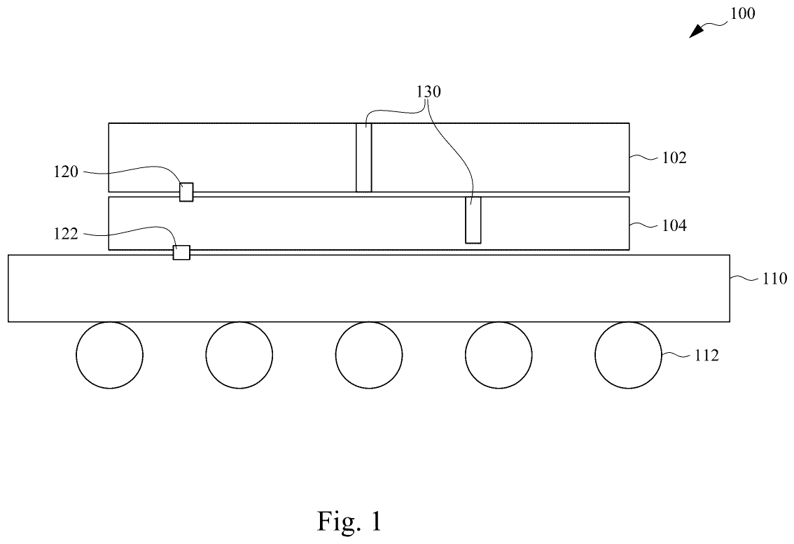

FIG. 1 illustrates a cross-sectional view of a semiconductor package (or device) 100 in accordance with various embodiments of the present disclosure. In one aspect, the semiconductor package 100 may sometimes be referred to as a three-dimensional integrated circuit (sometimes referred to as “3D IC”) with two or more levels of multiple semiconductor devices (sometimes referred to as “chips” or “dies”) stacked on top of one another. It should be understood that the semiconductor package 100 is simplified for illustrative purposes, and thus the arrangement of components of the semiconductor package 100 can be configured in various other manners and/or the semiconductor package 100 can include any of other components while remaining within the scope of the present disclosure.

In some embodiments of the present disclosure, the semiconductor package 100 includes a first die (e.g., top die) 102 and a second die (e.g., bottom die) 104 that are stacked on top of one another. The top die 102 and the bottom die 104 may be (e.g., electrically) bonded to each other through suitable bonding 120, for example, hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like.

In one embodiment of the present disclosure, the top die 102 may include multiple active circuits, devices, components, or loads, such as a system-on-chip (SoC) device, a high-bandwidth memory device (HBM) device, or the like, while the bottom die 104 may include one or more passive circuits, devices, and/or loads, such as an integrated passive device, an integrated voltage regulator, or the like. In another embodiment, the top die 102 may include both active and passive circuits, devices, and/or loads, and the bottom die 104 may also include both active and passive circuits, devices, and/or loads. In yet another embodiment, the top die 102 may include passive circuits, devices, and/or loads, while the bottom die 104 may also include active circuits, devices, and/or loads.

In some embodiments, the semiconductor package 100 further includes a package substrate 110, which may be (e.g., electrically) bonded to the bottom die 104 through suitable bonding 122. In some embodiments, the bonding 122 is hybrid bonding, micro bumps, direct bonding, chemically activated bonding, plasma activated bonding, anodic bonding, eutectic bonding, glass frit bonding, adhesive bonding, thermo-compressive bonding, reactive bonding and/or the like. In some embodiments, the package substrate 110 is a printed circuit board (PCB) or the like, which is made of a semiconductor material, such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used as the semiconductor material of the package substrate 110. Additionally, the package substrate 110 may be a Silicon on Insulator (SOI) substrate. Generally, an SOI substrate includes a layer of a semiconductor material such as epitaxial silicon, germanium, silicon germanium, SOI, SGOI, or combinations thereof. The package substrate 110 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for package substrate 110.

In some embodiments, the package substrate 110 may include metallization layers and vias, and bond pads over the metallization layers and vias. The metallization layers are designed to connect the various devices to form functional circuitry, which are sometimes referred to as package routes. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). Such package routes may later be shown in one or more of the following figures.

In some embodiments, the semiconductor package 100 further includes a number of conductive connectors 112 disposed on a side of the package substrate 110 opposite to its side facing the bottom die 104, as shown in FIG. 1. The conductive connectors 112 may be formed from a conductive material such as solder, copper, aluminum, gold, nickel, silver, palladium, tin, the like, or a combination thereof. In some embodiments, the conductive connectors 112 are formed by initially forming a layer of solder through methods such as evaporation, electroplating, printing, solder transfer, ball placement, or the like. Once a layer of solder has been formed on the structure, a reflow may be performed in order to shape the conductive connectors 112 into desired bump shapes. Such conductive connectors 112 can operatively serve as package pins of the semiconductor package 100 that are configured to receive one or more supply voltages, in some embodiments.

In some embodiments, as shown in FIG. 1, the semiconductor package 100 includes one or more TSVs 130. In some embodiments, a TSV 130 vertically extends through an entire die (e.g., 102). In other embodiments, a TSV 130 vertically extends through a large portion of an entire die (e.g., 104). Typically, a TSV 130 has a high aspect ratio of the depth to the diameter. In some embodiments, the aspect ratio of the TSV 130 is in a range from about 8:1 to about 20:1, and in other embodiments, the aspect ratio of the TSV 130 is in a range from about 12:1 to about 16:1. The TSV 130 can be used, along with other route components (such a interconnect metal traces and via), as a power rail or a signal rail to transfer power or signals from a die (e.g., die 102) to another die (e.g., die 104), and vice versa.

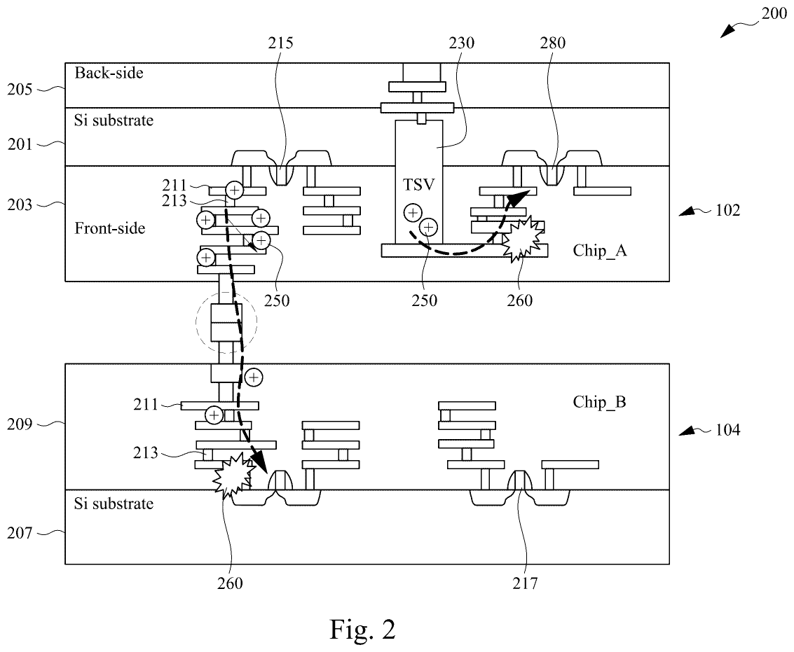

FIG. 2 is a cross-sectional view of a semiconductor package 200 illustrating a potential plasma process-induced damage (PID). The semiconductor package 200 includes a first die (e.g., top die) 102 and a second die (e.g., bottom die) 104 that are stacked on top of one another. In some embodiments, the first die 102 is flipped and is face-to-face bonded to the second die 104. In some embodiments, the first die 102 and the second die 104 may be (e.g., electrically) bonded to each other through using bonding techniques. In some embodiments, the first die 102 includes a first substrate 201, a front side 203, a backside 205, a TSV 230, a plurality of interconnects (such as metal traces 211 and vias 213), and one or more semiconductor devices or components (such as CMOS transistors) 215. Similarly, the second die 104 includes a second substrate 207, a front side 209, a plurality of interconnects (such as metal traces 211 and vias 213), and one or more semiconductor devices or components (such as CMOS transistors) 217. In some embodiments, a TSV 230 may extend through a large portion of the first die 102 (such as the first substrate 201 and the frontside 203). In other embodiments, the TSV 230 may entirely extend through the first die 102. In some embodiments, the TSV 230 functions to transfer power, and in other embodiments, the TSV 230 functions to transfer signals.

As shown in FIG. 2, during some processes of forming the TSVs 230, electrostatic charges 250 can be generated and accumulated in or near the TSVs 230. For example, in a plasma etching process during forming the TSVs 230, plasma induced electrostatic charges 250 can be generated and accumulated in or near the TSVs 230 or other components. In addition, during an operation process of the semiconductor package 200, electrostatic charges 250 can also be generated and accumulated in or near the TSVs 230 or other components. The electrostatic charges 250 accumulated in or near the TSVs 230 can cause damages (such as burning out) 260 to e.g., components, devices (such as an internal circuit 280), and interconnects (such as 211 and 213) that are connected to or nearby the TSV 230, when the accumulated electrostatic charges 250 are released in a sudden way. Thus, a space-friendly and efficient protective ESD scheme to discharge or release the accumulated electrostatic charges are highly desired.

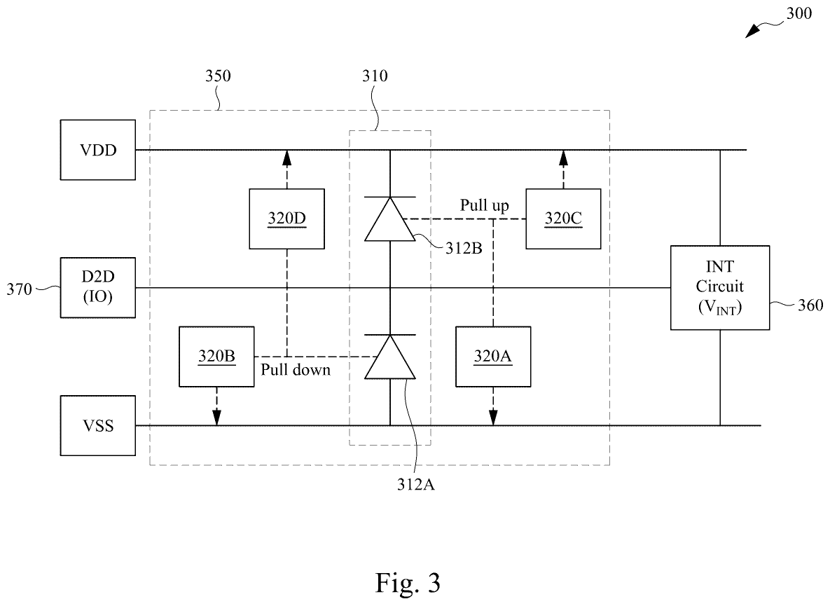

FIG. 3 illustrates a circuit 300 that includes a combo Silicon Controlled Rectifier (SCR) structure 350 coupled to an internal circuit 360 in accordance with some embodiments. In some embodiments, both the combo SCR structure 350 and the internal circuit 360 are coupled between a first power line Vss and a second power line Vdd. In some embodiments, the combo SCR structure 350 includes an ESD protection circuit 310 and one or more SCR components 320 (such as 320A, 320B, 320C or 320D). In some embodiments, the ESD protection circuit 310 includes a single charge dissipation element 312 (such as 312A or 312B) coupled between the first power line Vss and the second power line Vdd, and coupled to an input 370 of the internal circuit 360. In other embodiments, the ESD protection circuit 310 includes a pair of charge dissipation elements 312 (such as 312A and 312B) coupled in series between the first power line Vss and the second power line Vdd, and coupled to the input 370 of the internal circuit 360. In some embodiments, a charge dissipation element 312 is diode, and in other embodiment, a pair of charge dissipation elements 312 are a pair of diodes coupled in series.

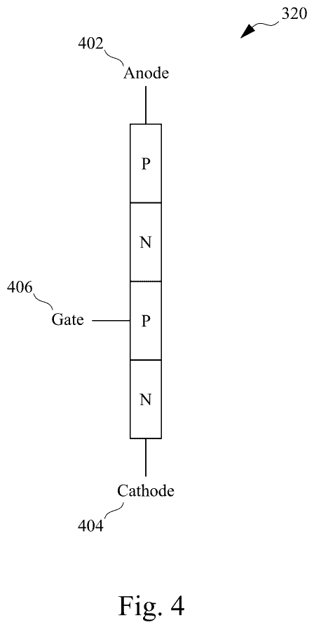

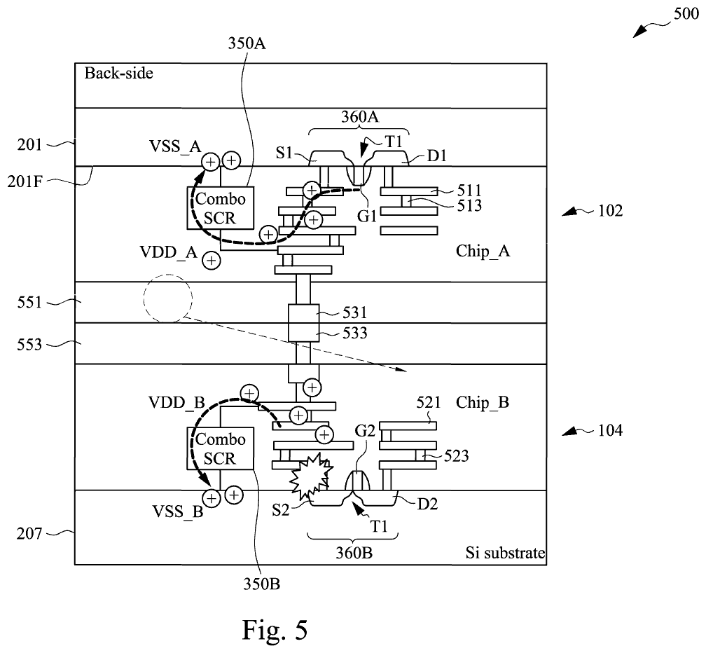

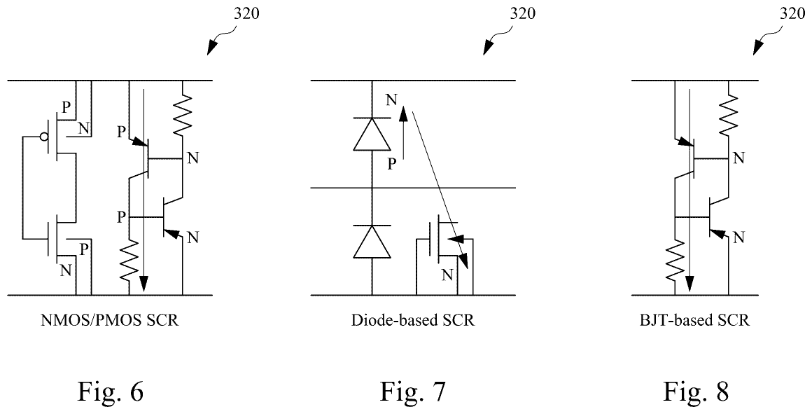

FIG. 4 illustrates an example Silicon Controlled Rectifier (SCR) component 320 in accordance with some embodiments. An SCR component (or an SCR) 320, also named as semiconductor-controlled rectifier, is a four-layer solid state current-controlling device. The SCR component is a type of thyristor. SCR components can be used in electronic devices that require control of high voltage and power. As shown in FIG. 4, an SCR component may have three junctions, and three terminals, namely, an anode 402, a cathode 404, and a gate 406. The SCR component may have four layers of semiconductors that form two structures, namely, NPNP or PNPN. The anode may connect to the P-type, the cathode may connect to the N-type and the gate may connect to the P-type. The SCR component 320 conducts when a gate pulse is applied to a gate 406 of the SCR component 320, just like a diode. More details about SRC components will be explained with respect to FIGS. 6, 7 and 8. FIG. 5 is a cross-sectional view of a semiconductor package 500 including one or more combo SCR structures 350 (such as 350A and 350B) as shown in FIG. 3 in accordance with some embodiments. The semiconductor package 500 includes a first die (e.g., top die) 102 and a second die (e.g., bottom die) 104 that are stacked on top of one another. In some embodiments, the first die 102 is flipped and is face-to-face bonded to the second die 104. In some embodiments, the first die 102 and the second die 104 may be (e.g., electrically) bonded to each other through using bonding techniques, such as hybrid bonding. Hybrid bonding is a semiconductor packaging technology that enables the direct bonding of two surfaces of semiconductor wafers or dies at both the metal and dielectric levels. Hybrid bonding can create high-density, low-resistance interconnects between layers of chips in 3D integrated circuits (ICs) and other advanced semiconductor devices. In hybrid bonding, the dielectric layers (such as silicon oxide) of the two surfaces are brought into contact. Because of the precision of the surface preparation, the dielectric layers can bond at an atomic level without the need for additional adhesives. This creates a strong, permanent bond between the two surfaces. In hybrid bonding, simultaneously, metal pads (such as copper) on the surfaces are also bonded together. This forms the electrical connections between the two chips or wafers, allowing for high-speed data transfer and low power consumption. The direct metal bonding creates low-resistance, high-conductivity interconnects. In 3D Integrated Circuits (3D ICs), for example, by using hybrid bonding technology, multiple layers of semiconductor devices are stacked vertically to create a more powerful and efficient system.

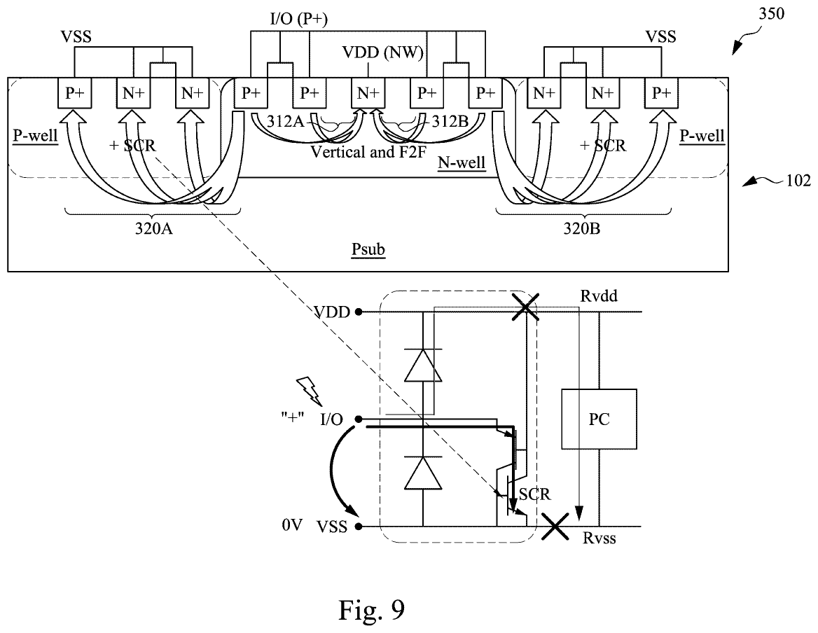

In some embodiments, as shown in FIG. 5, the first die 102 and the second die 104 are bonded together face to face by using a hybrid bonding structure, and the hybrid bonding structure includes e.g., at least one metal pad 531 in the first die 102 and at least one metal pad 533 in the second die 104, as well as a dielectric layer 551 in the first die 102 and a dielectric die 553 in the second die 104. In some embodiments, the first die 102 includes a first substrate 201, an internal circuit 360A, and a SCR structure 350A adjacent to the internal circuit 360A. In some embodiments, the internal circuit 360A includes a plurality of interconnects (such as metal traces 511 and vias 513), and one or more semiconductor devices or components (such as CMOS transistors) T1. The transistor T1 may include a source S1, a drain D1, and a gate G1. Similarly, in some embodiments, the second die 104 includes a second substrate 207, an internal circuit 360B, and a SCR structure 350B adjacent to the internal circuit 360B. In some embodiments, the internal circuit 360B includes a plurality of interconnects (such as metal traces 521 and vias 523), and one or more semiconductor devices or components (such as CMOS transistors) T2. The transistor T2 may include a source S2, a drain D2, and a gate G2. As shown in FIG. 3, a combo SCR structure 350 includes at least one charge dissipation element 312 and at least one SCR component 320 adjacent to the at least one charge dissipation element 312. The details of the combo SCR structure 350 are described in more details afterwards (e.g., in FIG. 9). As shown in FIG. 5, for example, in the first die 102, a combo SCR structure 350A is vertically disposed between a first power line Vss_A and a second power line Vdd_A, and laterally disposed adjacent to a first internal circuit 360A, and similarly in the second die 104, a combo SCR structure 350B is vertically disposed between a first power line Vss_B and a second power line Vdd_B, and laterally disposed adjacent to a second internal circuit 360B.

Referring to FIGS. 3, 4 and 5, in the first die 102, when accumulated charges in or near the internal circuit 360A are high enough, a gate impulse will be applied to the gate 406 of the SCR component 320 of the combo SCR structure 350A, and this SCR component 320 will conduct, just conducting like a diode. As such, the combo SCR structure 350A will conduct, and a current path will be created, so that the accumulated charges in the internal circuit 360A will be discharged from the internal circuit 360A through the combo SCR structure 350A to a substrate 201 (or GND) of the first die 102. Similarly, in the second die 104, when accumulated charges in the internal circuit 360B are high enough, a gate impulse will be applied to the gate 406 of the SCR component 320 of the combo SCR structure 350B, and this SCR component 320 will conduct, just conducting like a diode. As such, the combo SCR structure 350B will conduct, and a current path will be created, so that the accumulated charges in the internal circuit 360B will be discharged from the internal circuit 360B through the combo SCR structure 350B to a substrate 207 (or GND) of the second die 104. Therefore, such a tap-less combo SCR layout solution by combining an ESD protection device and one or more SCR components can assist or enhance ESD/PID discharge performance, and can cover all ESD discharge path, and thus can free Rvdd/Rvss of power bus, thereby advantageously improving the package performance and reducing penalty area for the ESD protection device of the package.

FIGS. 6, 7 and 8 illustrate various SCR components 320 in accordance with some embodiments. An SCR component can be a N/PMOS, a N/P Diode, or a BJT to form a parasitic PNPN structure. In some embodiments, as shown in FIG. 6, the SCR component 320 is a N/PMOS SCR component. In other embodiments, as shown in FIG. 7, the SCR component 320 is a diode-based SCR component. In still other embodiments, as shown in FIG. 8, the SCR component 320 is a BJT SCR component. It is understood that the SCR components can be other parasitic PNPN components or structures than NMOS/PMOS SCR components, diode-based SCR components, and BJT SCR components, while remaining within the scope of the present disclosure.

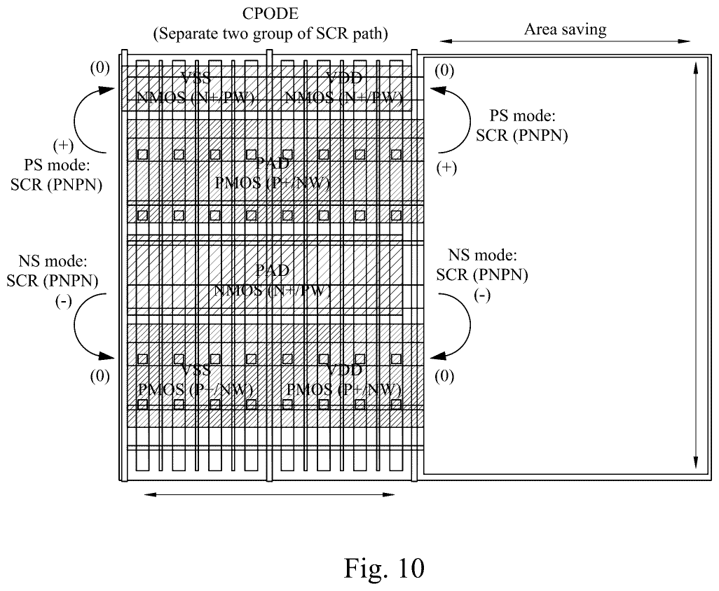

FIG. 9 is a cross-sectional view of an example combo SCR structure 350 in a die (e.g., a first die 102) of a package 500 in FIG. 5 in accordance with some embodiments. As shown in FIG. 9, in the first die 102, the combo SCR structure 350 includes an ESD protection circuit 310 including charge dissipation elements (such as diodes) 312A and 312B, and SCR components 320A and 320B (for example, each in PNPN form) formed laterally adjacent to the diodes 312A and 312B, respectively. In some embodiments, the charge dissipation diode 312A of the ESD protection circuit 310 have two P+ nodes and one N+ node, which are formed in a N-well, and the charge dissipation diode 312B of the ESD protection circuit 310 have two P+ nodes and one N+ node, which are also formed in the N-well. The charge dissipation diodes 312A and 312B share the N+ node, which is coupled to a power line Vdd. The four P+ nodes of the charge dissipation diodes 312A and 312B are commonly coupled to an I/O terminal of the ESD protection circuit 310. In some embodiments, the SCR component 320A is formed in a P-well laterally on one side of the ESD protection circuit 310, and the SCR component 320B is formed in another P-well laterally on another side of the ESD protection circuit 310. The SCR typically has alternating p-type and n-type regions to form a PNPN structure (as shown in FIG. 4), which is the basis of its ability to conduct and latch in response to a voltage spike. In some embodiments, the SCR component 320A has one P+ node, and two N+ nodes, coupled to another power line Vss, and the SCR component 320B has one P+ node, and two N+ nodes, also coupled to the other power line Vss. As such, the combo SCR structure 350 does not have a tap structure (which needs to have e.g., a P+ node in a P-well or a N+ node in a N-well), and thus can free Rvdd/Rvss of power bus and still can cover all ESD discharge paths (PS/NS/PD/ND modes) as shown in FIG. 10. FIG. 10 illustrates a layout 1000 of the SCR structure 350 in accordance with some embodiments. As shown in FIGS. 9 and 10, such a tap-less combo SCR layout can accompany and separate groups of SCR paths with the combo SCR ESD device usage, and thus bring about benefits to free Rvdd/Rvss of power bus to make it have ESD self-protection capability and to save penalty areas in the package, thereby advantageously improving package performance and package density. As shown in FIG. 10, the SCR layout 1000 without any tap effort can solve all ESD events such as PS/PD/NS/ND modes at the same time. In some embodiments, as shown in FIG. 10, a Contact Poly Over Active with Dummy Extension (CPODE) is used to separate PS/PD/NS/ND modes in the SCR ESD protection structure in a left-to-right direction. Here, PS stands for a P-substrate, which is a type of substrate used in semiconductor fabrication where the majority carriers are holes. PD stands for a P-diffusion, which refers to a region in the semiconductor that is heavily doped with p-type impurities. NS stands for a N-substrate, which is a type of substrate where the majority carriers are electrons. ND stands for a N-diffusion, which refers to a region that is heavily doped with n-type impurities.

In some embodiments, combo SCR cells can accompany with IO cells that are within or less than 10 um, and hybrid-bond (HB) pitches also can be directly dropped in the ESD protection device. In the present disclosure, such a combo SCR design can be directly dropped in a Digital (Fin Bound) FB ESD solution for 3DIC higher density die-to-die (D2D) interface (HB pitch 5-7/3.5-5.5 um). The present disclose can advantageously save about 80% penalty areas for the ESD protection circuit or device.

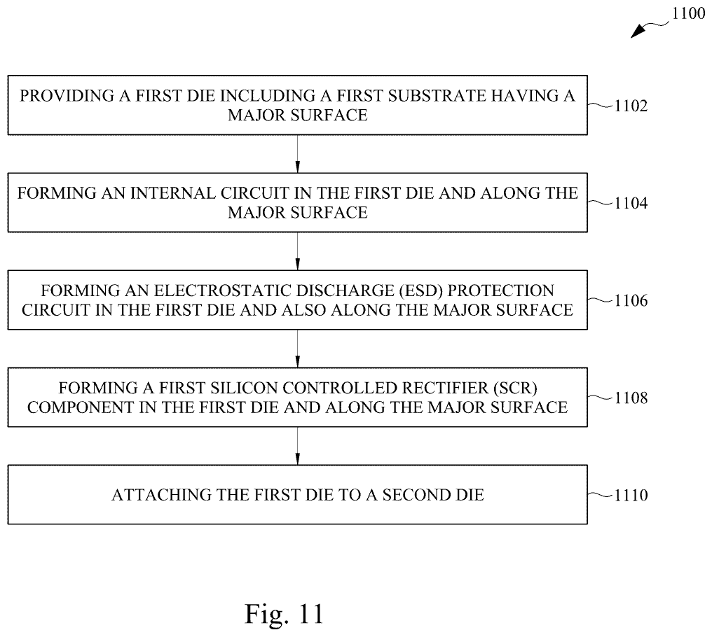

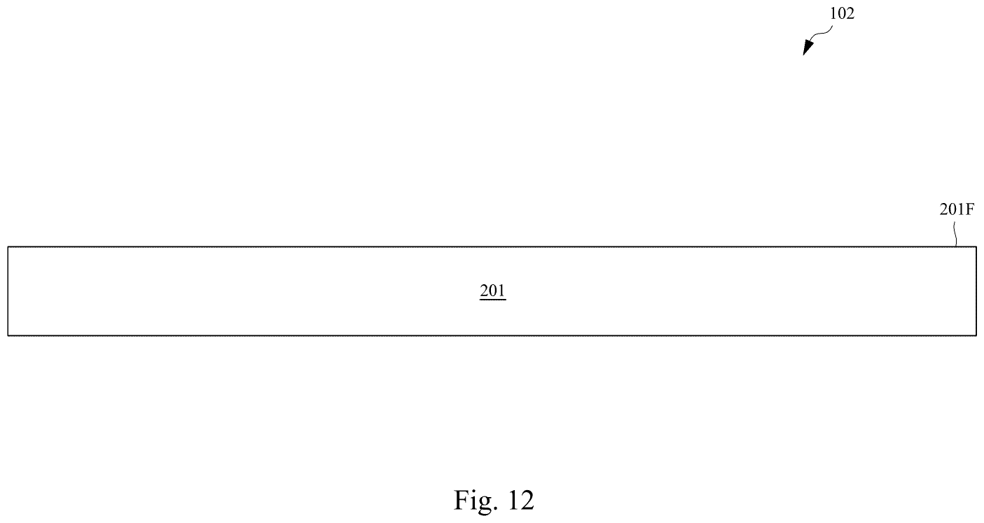

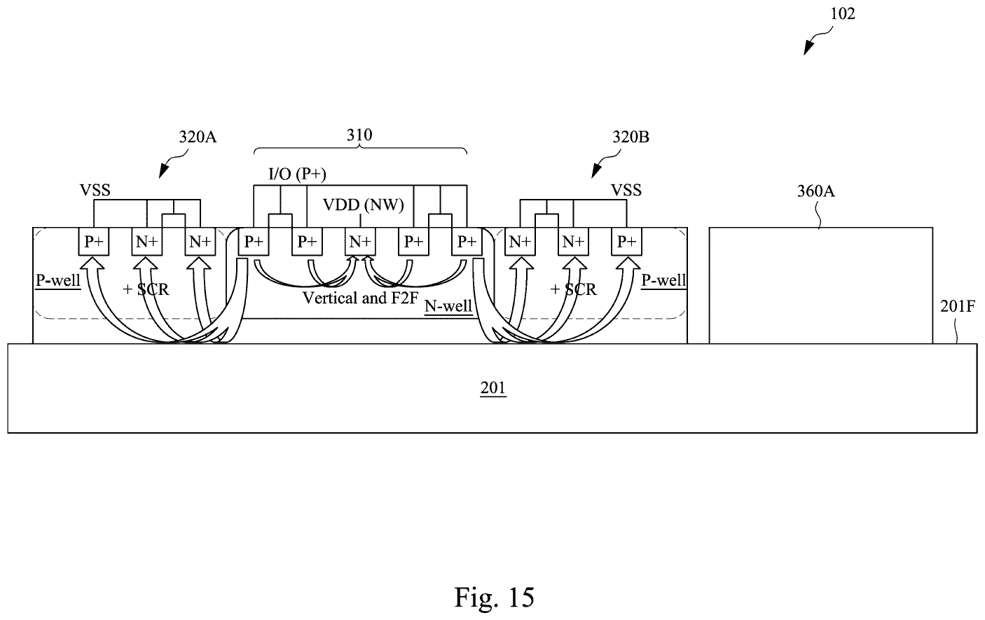

FIG. 11 is an example flowchart of a method 1100 for fabricating the semiconductor package 500 in FIG. 5 in accordance with some embodiments. FIGS. 12, 13, 14, 15 and 16 are cross-sectional views of the semiconductor package 500 of FIG. 5 at various stages of the method of FIG. 11 in accordance with some embodiments. It should be noted that the method 1100 is merely an example, and is not intended to limit the present disclosure. Accordingly, it is understood that the order of operations of the method 1100 of FIG. 11 can change, that additional operations may be provided before, during, and after the method 1100 of FIG. 11, and that some other operations may only be described briefly herein.

Such a semiconductor package 500 fabricated by the method 1100 may include at least a first (e.g., top) die 102 and a second (e.g., bottom) die 104 that are operatively and physically coupled to each other. For example, some components and functions of the semiconductor package 500 are described in for example FIGS. 3-9. Accordingly, operations of the method 1100 will be discussed in conjunction with the components discussed with respect to FIGS. 3-9.

Referring to FIGS. 5, 12 and 11, the method 1100 starts with operation 1102 of providing a first die 102 including a first substrate 201 having a major surface 201F. For example, the first substrate 201 may be made of a semiconductor material, such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the first substrate 201 may be a SOI substrate. Generally, an SOI substrate includes a layer of a semiconductor material such as epitaxial silicon, germanium, silicon germanium, SOI, SGOI, or combinations thereof.

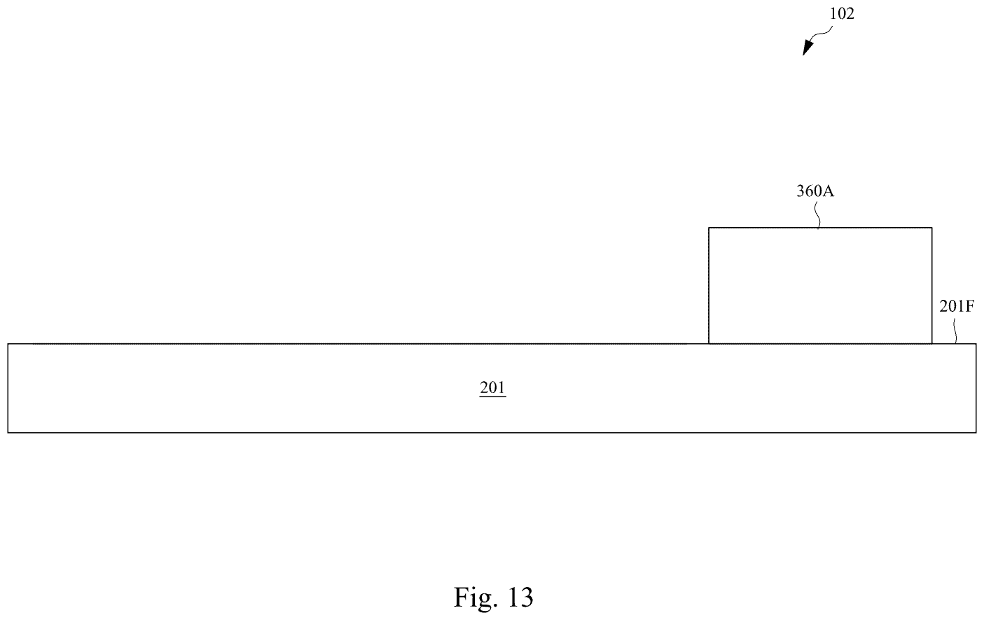

Next, referring to FIGS. 5 and 13, the method 1100 proceeds to operation 1104 of forming an internal circuit 360A in the first die 102 and along the major surface 201F of the first substrate 201. For example, the internal circuit 360A includes an input/output terminal 370 as shown in FIG. 3. Specifically, the internal circuit 360A in the first die 102 can be formed by various semiconductor fabricating processes, such as photolithography, etching, filling of metal, and CMP processes. During the processes of forming the internal circuit 360A in the first die 102, electrostatic charges can be generated and accumulated in or near the internal circuit 360A, which are potentially harmful to the internal circuit 360A. In addition, other components such as TSVs 230 (as shown in FIG. 2) can be formed and extend through the first substrate 201 of the first die 102. Specifically, the TSVs 230 can be formed by semiconductor fabricating processes, such as photolithography, etching, filling of metal, and CMP processes. During the processes of forming the TSVs 230, electrostatic charges can be generated and accumulated in or near the TSVs 230, which are potentially harmful to an internal circuit 360A near or connected to the TSVs 230.

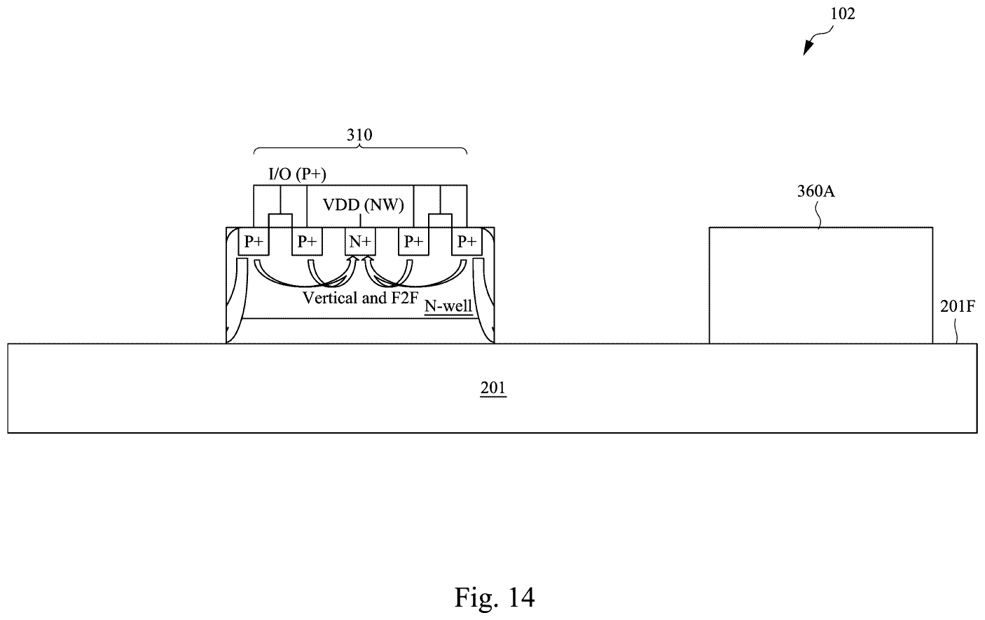

Next, referring to FIGS. 3, 5, 9, 14 and 11, the method 1100 proceeds to operation 1106 of forming an electrostatic discharge (ESD) protection circuit 310 in the first die 102 and also along the major surface 201F of the substrate 201. In some embodiments, the ESD protection circuit 310 is disposed laterally spaced from the internal circuit 360. In some embodiments, the ESD protection circuit 310 includes a single charge dissipation element (such as 312A or 312B), and in other embodiments, the ESD protection circuit 310 includes a pair of a first charge dissipation element 312A and a second charge dissipation element 312B as shown in FIGS. 9 and 14. In some embodiments, a charge dissipation element (such as 312A or 312B) is a diode. Specifically, the ESD protection circuit 310 can be formed by various semiconductor fabricating processes, such as photolithography, etching, filling of metal, and CMP processes.

Next, referring to FIGS. 5, 9, 15 and 11, the method 1100 proceeds to operation 1108 of forming a first Silicon Controlled Rectifier (SCR) component 320 (such as 320A) in the first die 102 and along the major surface 201F of the substrate 201. In some embodiments, the first SCR component 320A is disposed laterally adjacent to and spaced from the first charge dissipation element first 312A (as shown in FIGS. 3 and 9), and is vertically adjacent to the first power line Vss or the second power line Vdd. The SCR component 320 is a type of thyristor, and can conduct when a gate pulse is applied to a gate 406 (in FIG. 4) of the SCR component 320, just like a diode. As shown in FIG. 4, an SCR component 320 has four layers of semiconductors that form two structures, namely, NPNP or PNPN. In addition, the SCR component 320 has three junctions, and three terminals, namely, an anode 402, a cathode 404, and a gate 406. For example, the anode 402 connects to the P-type, the cathode 404 connects to the N-type and the gate 406 connects to the P-type. More details about an SRC component 320 will be explained with respect to FIGS. 6, 7 and 8.

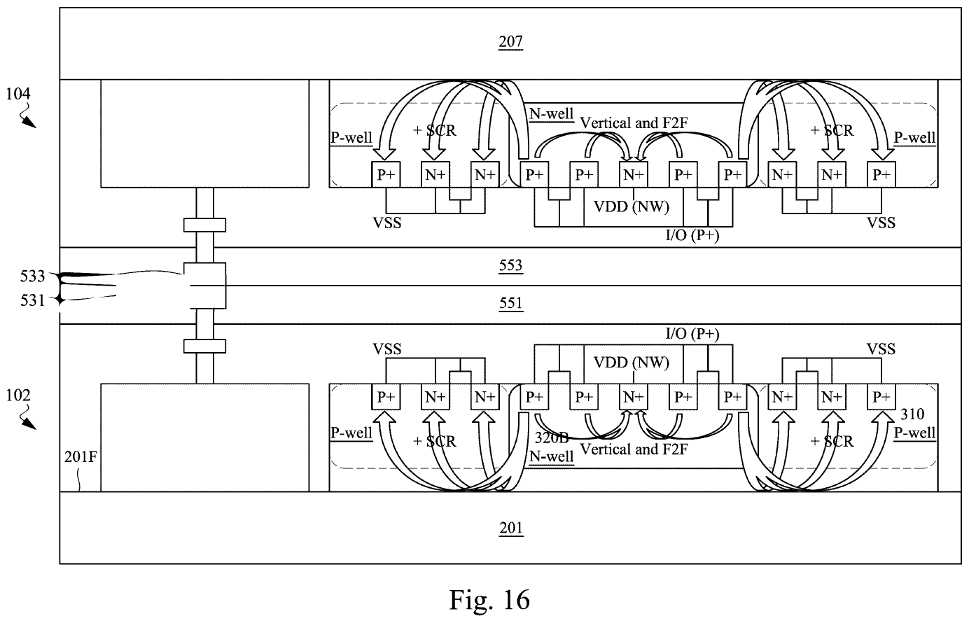

Next, referring to FIGS. 5, 16 and 11, the method 1100 proceeds to operation 1110 of attaching the first die 102 to a second die 104. In some embodiments, the first die 102 and the second die 104 may be (e.g., electrically) bonded to each other through using bonding techniques. In some embodiments, as shown in FIGS. 5 and 16, the first die 102 and the second die 104 are bonded together face to face by using a hybrid bonding structure, and the hybrid bonding structure includes e.g., at least one metal pad 531 in the first die 102 and at least one metal pad 533 in the second die 104, as well as a dielectric layer 551 in the first die 102 and a dielectric die 553 in the second die 104. In one embodiment of the present disclosure, the first die 102 may include multiple active circuits, devices, components, or loads, such as a system-on-chip (SoC) device, a high-bandwidth memory device (HBM) device, or the like, while the second die 104 may include one or more passive circuits, devices, and/or loads, such as an integrated passive device, an integrated voltage regulator, or the like. In another embodiment, the first die 102 may include both active and passive circuits, devices, and/or loads, and the second die 104 may also include both active and passive circuits, devices, and/or loads. In yet another embodiment, the first die 102 may include passive circuits, devices, and/or loads, while the second die 104 may also include active circuits, devices, and/or loads.

In some embodiments, the first SCR component 320 is a PMOS SCR or a NMOS SCR (as shown in FIG. 6). In other embodiments, the first SCR component 320 is a diode-based SCR (as shown in FIG. 7). In still other embodiments, the first SCR component 320 is a bipolar junction transistor (BJT) SCR (as shown in FIG. 8).

In some embodiments, also as shown in FIG. 3, the first charge dissipation element 312A is electrically coupled between a first power line Vss and a second power line Vdd, and the first SCR component (such as 320A or 320B) is adjacent to one (such as Vss) of the first power line Vss and the second power line Vdd. Also as shown in FIGS. 3, 4 and 5, in the first die 102, when accumulated charges in or near the internal circuit 360A are high enough, a gate impulse will be applied to the gate 406 of a SCR component 320 (such as 320A) of the combo SCR structure 350A, and this SCR component 320A will thus conduct, just performing like a diode.

As such, the combo SCR structure 350A will conduct, and a current path will be created so that the accumulated charges in or near the internal circuit 360A will be discharged from the internal circuit 360A through the combo SCR structure 350A to a substrate 201 (or GND) of the first die 102. Therefore, such a tap-less combo SCR design or arrangement by combining an ESD protection device and SCR component(s) can assist ESD/PID discharge performance and cover all ESD discharge path, thereby advantageously improving performance of the package and reducing the size of the package.

In one aspect of the present disclosure, a semiconductor package is disclosed. The semiconductor package includes a first die that includes an internal circuit disposed along a major surface of a substrate; an electrostatic discharge (ESD) protection circuit also disposed along the major surface, laterally adjacent to and spaced from the internal circuit, and comprising a first charge dissipation element; and a first Silicon Controlled Rectifier (SCR) component laterally adjacent to and spaced from the first charge dissipation element.

In another aspect of the present disclosure, a semiconductor die is disclosed. The semiconductor die includes a substrate; an electrostatic discharge (ESD) protection circuit disposed along a major surface of the substrate, laterally spaced from an internal circuit also disposed along the major surface, and including a first charge dissipation element coupled between a first power line and a second power line; and a first Silicon Controlled Rectifier (SCR) component laterally adjacent to and spaced from the first charge dissipation element.

In yet another aspect of the present disclosure, a method for forming semiconductor packages is disclosed. The method includes providing a first die including a first substrate having a major surface; forming an internal circuit in the first die and along the major surface; forming an electrostatic discharge (ESD) protection circuit in the first die and also along the major surface, the ESD protection circuit being laterally spaced from the internal circuit and having a first charge dissipation element; forming a first Silicon Controlled Rectifier (SCR) component in the first die and along the major surface, the first SCR component being laterally adjacent to and spaced from the first charge dissipation element first; and attaching the first die to a second die.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die comprising:
an internal circuit disposed on a substrate;
an electrostatic discharge (ESD) protection circuit on the substrate, laterally adjacent to and spaced from the internal circuit, and comprising a first charge dissipation element; and
a first Silicon Controlled Rectifier (SCR) component laterally adjacent to and spaced from the first charge dissipation element.

2. The semiconductor package of claim 1, wherein the first charge dissipation element is a first diode.

3. The semiconductor package of claim 1, wherein the ESD protection circuit further comprises a second charge dissipation element that is electrically coupled to the first charge dissipation element in series.

4. The semiconductor package of claim 3, wherein the second charge dissipation element is a second diode.

5. The semiconductor package of claim 1, further comprising a second die vertically coupled to the first die by a bonding interface, wherein the bonding interface includes a plurality of hybrid bonds.

6. The semiconductor package of claim 1, wherein the first charge dissipation element is electrically coupled between a first power line and a second power line.

7. The semiconductor package of claim 6, wherein the first SCR component is adjacent to one of the first power line and the second power line.

8. The semiconductor package of claim 1, wherein the first SCR component is selected from a group consisting of a PMOS transistor, a NMOS transistor, a diode, and a bipolar junction transistor (BJT).

9. The semiconductor package of claim 1, wherein the first die further comprises a second SCR component laterally adjacent to and spaced from the first charge dissipation element, and wherein the first SCR and the second SCR component are laterally disposed at opposite sides of the first charge dissipation element.

10. The semiconductor package of claim 9, wherein the second SCR component is selected from a group consisting of a PMOS transistor, a NMOS transistor, a diode, and a bipolar junction transistor (BJT).

11. A semiconductor die, comprising:
a substrate;
an electrostatic discharge (ESD) protection circuit disposed along a major surface of the substrate, laterally spaced from an internal circuit disposed along the major surface, and comprising a first charge dissipation element coupled between a first power line and a second power line; and
a first Silicon Controlled Rectifier (SCR) component laterally adjacent to and spaced from the first charge dissipation element.

12. The semiconductor die of claim 11, wherein the semiconductor die is vertically coupled to another semiconductor die by a bonding interface, and wherein the bonding interface includes a plurality of micro-bumps or hybrid bonds.

13. The semiconductor die of claim 11, wherein the first power line is a Vdd power line and the second power line is a Vss power line.

14. The semiconductor die of claim 11, wherein the first SCR component is selected from a group consisting of a PMOS transistor, a NMOS transistor, a diode, and a bipolar junction transistor (BJT).

15. The semiconductor die of claim 11, wherein the first charge dissipation element is a first diode.

16. The semiconductor die of claim 11, wherein the ESD protection circuit further comprises a second charge dissipation element that is electrically coupled to the first charge dissipation element in series.

17. The semiconductor die of claim 16, wherein the second charge dissipation element is a second diode.

18. A method for forming a semiconductor package, comprising:
providing a first die including a first substrate having a major surface;
forming an internal circuit in the first die and along the major surface;
forming an electrostatic discharge (ESD) protection circuit in the first die and along the major surface, wherein the ESD protection circuit is laterally spaced from the internal circuit and comprises a first charge dissipation element;
forming a first Silicon Controlled Rectifier (SCR) component in the first die and along the major surface, wherein the first SCR component is laterally adjacent to and spaced from the first charge dissipation element first; and
attaching the first die to a second die.

19. The method of claim 18, wherein the first SCR component is selected from a group consisting of a PMOS transistor, a NMOS transistor, a diode, and a bipolar junction transistor (BJT).

20. The method of claim 18, wherein the first charge dissipation element is electrically coupled between a first power line and a second power line, and wherein the first SCR component is adjacent to one of the first power line and the second power line.
